(19) United States
(12) Patent Application Publication
(10) Pub. No.: US 2025/0287758 A1
(43) Pub. Date: Sep. 11, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., Ltd., Yongin-Si (KR)

(72) Inventors: WONJOON CHOI, Yongin-si (KR); SEUL-GI KIM, Yongin-si (KR); DOOHYUN KIM, Yongin-si (KR)

(21) Appl. No.: 19/050,115

(22) Filed: Feb. 11, 2025

(30) Foreign Application Priority Data
Mar. 7, 2024 (KR) 10-2024-0032789

(51) Int. Cl. H10H 29/855; H10H 29/01

(52) U.S. Cl. CPC H10H 29/8552; H10H 29/0363

(57) ABSTRACT

A display device is disclosed that includes a display panel including a light emitting diode, a window layer disposed on the display panel, a light blocking member including a first light blocking part disposed between the display panel and the window layer and a second light blocking part disposed between the display panel and the first light blocking part and partially covering a lower surface of the first light blocking part and a dam disposed between the light blocking member and the display panel.

### CROSS-REFERENCE TO RELATED APPLICATION

This application claims priority to Korean Patent Application No. 10-2024-0032789, filed on Mar. 7, 2024, and all the benefits accruing therefrom under 35 U.S.C. § 119, the content of which in its entirety is herein incorporated by reference.

### BACKGROUND

### 1. Field

The present disclosure relates to a display device, a method of manufacturing the display device, and an electronic device including the display device. More specifically, the present disclosure relates to the display device that provides visual information, the method of manufacturing the display device, and the electronic device including the display device.

### 2. Discussion of the Background

Generally, a display device includes a display area where an image is displayed and a peripheral area, which is a non-display area surrounding the display area. The display device may have a structure in which a dam is formed in the peripheral area (or a display area, if needed) due to process necessity, etc. The dam may prevent an adhesive part from overflowing out of a display panel. Accordingly, the dam may serve to prevent the adhesive part from overflowing. In other words, the dam must have a sufficient height to prevent the adhesive part from overflowing.

In addition, the dam itself must not overflow beyond the display panel so that a user does not have visual limitations when using the display device. Accordingly, research is being conducted to increase a height of the dam to prevent the adhesive part from overflowing, and to increase a slope of the dam itself to prevent it from overflowing beyond the display panel.

### SUMMARY

A purpose of the present disclosure is to provide a display device with improved display quality.

Another purpose of the present disclosure is to provide a method of manufacturing the display device.

Still another purpose of the present disclosure is to provide an electronic device including the display device.

A display device according to an embodiment of the present disclosure includes a display panel including a light emitting diode, a window layer disposed on the display panel, a light blocking member including a first light blocking part disposed between the display panel and the window layer and a second light blocking part disposed between the display panel and the first light blocking part and partially covering a lower surface of the first light blocking part and a dam disposed between the light blocking member and the display panel.

In an embodiment, the second light blocking part may be disposed contacting a lower surface of the first light blocking part.

In an embodiment, the light blocking member may have a step due to a difference between a width of the first light blocking part and a width of the second light blocking part in a plan view.

In an embodiment, a thickness of the second light blocking part may be about 6 μm to about 20 μm.

In an embodiment, a sum of the thickness of the second light blocking part and a thickness of the dam may be about 50 μm to about 200 μm.

In an embodiment, an end of the second light blocking part and an end of the display panel may coincide with each other in a plan view.

In an embodiment, an end of the second light blocking part and an end of the dam may coincide with each other in a plan view.

In an embodiment, the dam may be disposed contacting a lower surface of the second light blocking part and may be spaced apart from a lower surface of the first light blocking part.

In an embodiment, the dam may entirely cover a lower surface of the second light blocking part.

In an embodiment, the second light blocking part and the dam may have a same planar area in a plan view.

In an embodiment, the display device may further include an adhesive part disposed between the display panel and the window layer.

In an embodiment, a lower surface of the dam and a lower surface of the adhesive part with respect to a lower surface of the window layer may have a same level in a cross-sectional view.

In an embodiment, the light blocking member may surround the adhesive part in a plan view.

In an embodiment, the dam may surround the adhesive part in a plan view.

In an embodiment, the dam and the adhesive part may include a same material.

In an embodiment, the dam and the adhesive part may be transparent.

A method of manufacturing the display device according to an embodiment of the present disclosure includes forming a first light blocking part on a window layer, forming a second light blocking part on the first light blocking part partially covering a surface of the first light blocking part and forming a dam on the second light blocking part.

In an embodiment, in forming the dam on the second light blocking part, an end of the dam may be formed to coincide with an end of the second light blocking part in a plan view.

In an embodiment, in forming the dam on the second light blocking part, the dam may be formed to entirely cover a lower surface of the second light blocking part.

In an embodiment, in forming the dam on the second light blocking part, the dam may be formed contacting with a lower surface of the second light blocking part and spaced apart from a lower surface of the first light blocking part.

An electronic device according to an embodiment of the present disclosure includes a display device and a processor configured to drive the display device, and wherein the display device includes a display panel including a light emitting diode, a window layer disposed on the display panel, a light blocking member including, a first light blocking part disposed between the display panel and the window layer and a second light blocking part disposed between the display panel and the first light blocking part and partially covering a lower surface of the first light blocking part, and a dam disposed between the light blocking member and the display panel.

A display device according to an embodiment of the present disclosure includes a display panel including a light emitting diode, a window layer disposed on the display panel, a light blocking member including a first light blocking part disposed between the display panel and the window layer and a second light blocking part disposed between the display panel and the first light blocking part and partially covering a lower surface of the first light blocking part and a dam disposed between the light blocking member and the display panel.

Accordingly, as the second light blocking part is disposed on the first light blocking part, a thickness of the dam may be lower than when the second light blocking part is not present. As a height of the dam decreases, a spread of the dam is minimized, and a lateral slope of the dam may be formed close to vertical. Accordingly, the dam may be formed so as not to overflow on a light blocking member. As a result, the dam does not contact with the window layer, thereby providing an excellent visual experience to users of the display device.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view showing a display device according to an embodiment of the present disclosure.

FIG. 2 is a cross-sectional view taken along line I-I′ of the display device of FIG. 1.

FIG. 3 is a cross-sectional view showing the display panel of FIG. 2.

FIG. 4 is an enlarged cross-sectional view of part A of FIG. 2.

FIGS. 5 to 17 are views showing a manufacturing method for forming the light blocking member and the dam of FIG. 4.

FIG. 18 is block-diagram for showing an electronic device according to an embodiment of the disclosure.

FIG. 19 is schematic views for showing the electronic device according to various embodiments of FIG. 18.

### DETAILED DESCRIPTION

Illustrative, non-limiting embodiments will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. That is, the third direction D3 may be perpendicular to the plane formed by the first direction D1 and the second direction D2.

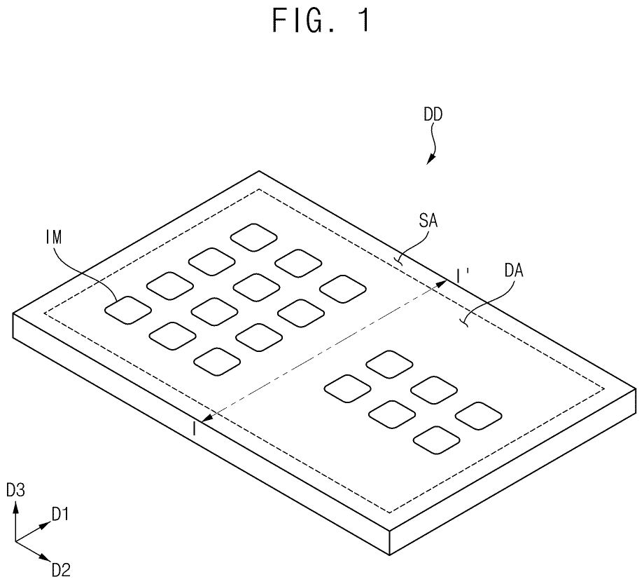

FIG. 1 is a perspective view showing a display device according to an embodiment of the present disclosure.

Referring to FIG. 1, the display device DD may include a display area DA and a peripheral area SA. The display area DA may be surrounded by the peripheral area SA.

The display area DA may be an area that may display an image by generating light or adjusting a transmittance of light provided from an external light source. The peripheral area SA may be an area that does not display an image. However, embodiments of the present disclosure are not limited thereto, and at least a portion of the peripheral area SA may display an image.

The display area DA may display a plurality of images IM. Users may receive information from the display device DD through the plurality of images IM.

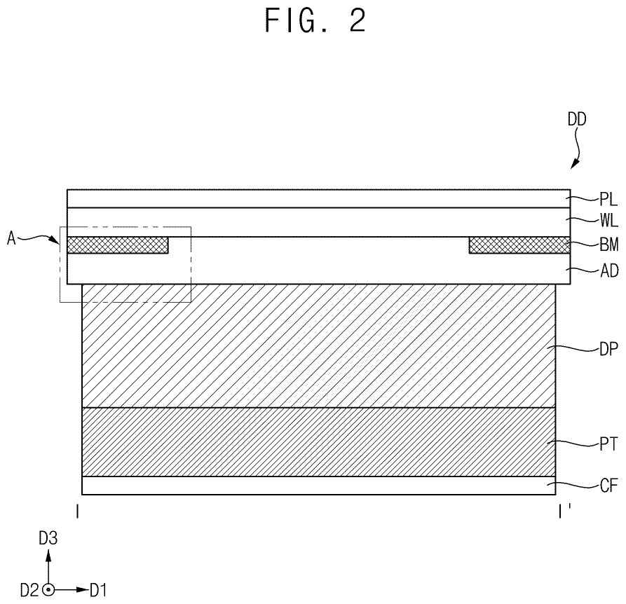

FIG. 2 is a cross-sectional view taken along line I-I′ of the display device of FIG. 1.

Referring to FIG. 2, the display device DD may include a cover film CF, a plate PT, a display panel DP, an adhesive part AD, a light blocking member BM, a window layer WL, and a protective film PL.

The cover film CF may be disposed on a back of the display device DD to protect the display device DD from external impacts. For example, the cover film CF may include at least one of polyurethane (PU), thermoplastic polyurethane (TPU), silicone (Si), and polydimethylacrylamide (PDMA). These may be used alone or in combination with each other. However, embodiments of the present disclosure are not limited thereto.

The plate PT may be disposed on the cover film CF. The plate PT may support the display panel DP and protect the display device DD from external impacts. That is, the plate PT may maintain the display panel DP in a relatively flat state even when an external force is applied from outside the display device DD. The plate PT may include a rigid or semi-rigid material. For example, the plate PT may include at least one of iron, chromium, carbon, nickel, silicon, manganese, and molybdenum. These may be used alone or in combination with each other. However, embodiments of the present disclosure are not limited thereto.

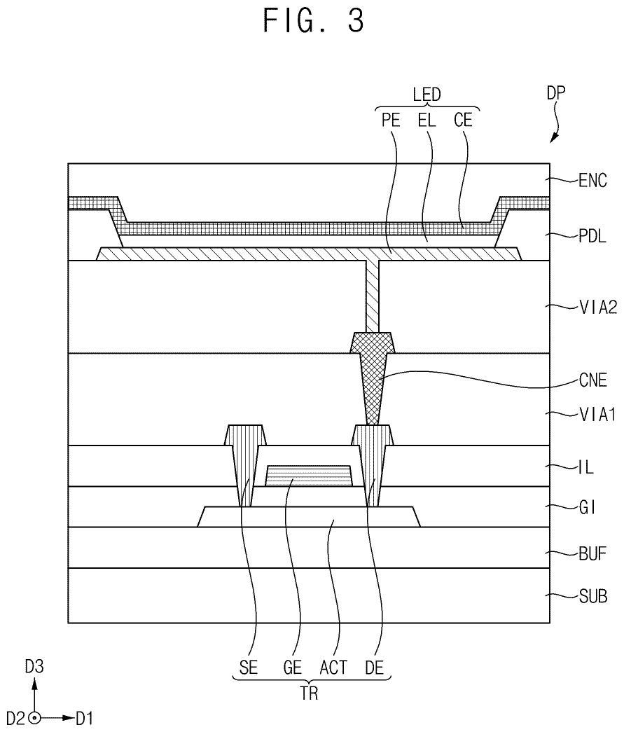

The display panel DP may be disposed on the plate PT. The display panel DP may receive electrical signals and emit light so that the display device DD may provide visual information to users. For example, the display panel DP may be either organic light emitting or inorganic light emitting. However, embodiments of the present disclosure are not limited thereto. The display panel DP will be described in detail later with reference to FIG. 3.

The adhesive part AD may be disposed on the display panel DP. The adhesive part AD may adhere display panel DP and components disposed thereon. For example, the adhesive part AD may adhere window layer WL and the display panel DP. The adhesive part AD may include pressure sensitive adhesive (PSA), optical clear adhesive (OCA), or optical clear resin (OCR). However, embodiments of the present disclosure are not limited thereto.

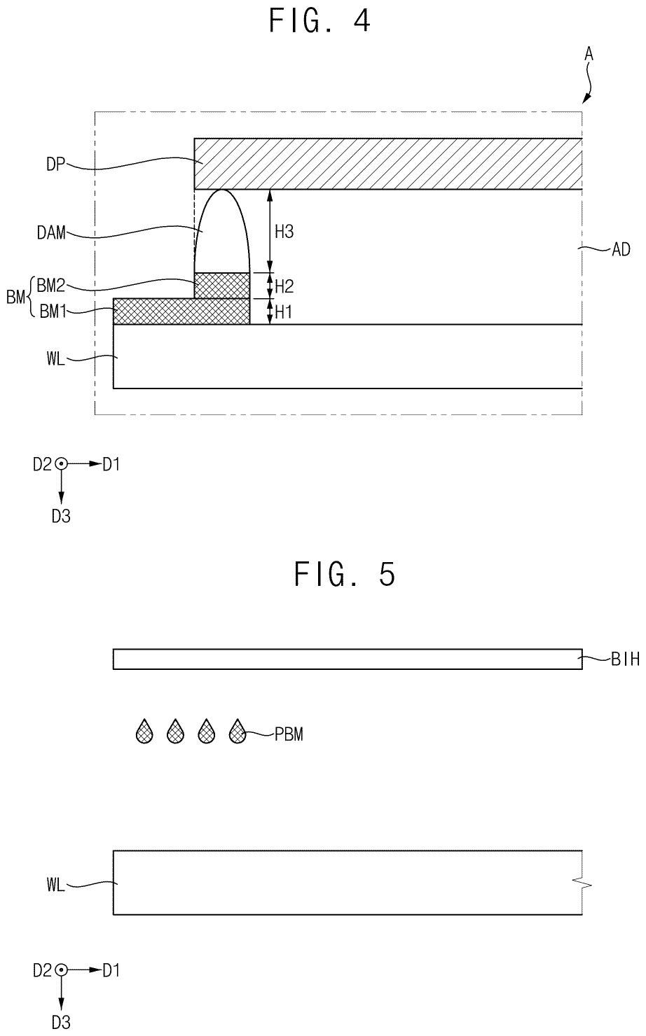

The light blocking member BM may be disposed on the adhesive part AD. The light blocking member BM may provide convenience to users by blocking light coming from a rear of the display device DD. For example, the light blocking member BM may include a light absorbing material. For example, the light blocking member BM may include an inorganic black pigment or an organic black pigment. The inorganic black pigment may be carbon black. The organic black pigment may include at least one of Lactam Black, Perylene Black, and Aniline Black. These may be used alone or in combination with each other. However, embodiments of the present disclosure are not limited thereto. The light blocking member BM will be described in detail later with reference to FIG. 4.

The window layer WL may be disposed on the adhesive part AD. The window layer WL may include a substantially transparent material. For example, the window layer WL may be glass or plastic. However, embodiments of the present disclosure are not limited thereto.

The protective film PL may be disposed on the window layer WL. The protective film PL may protect the window layer WL from front impacts, scratches, etc. The protective film PL may include a single-layer and/or multi-layer structure. For example, the protective film PL may include at least one of a base layer, a hard coating layer, a low refractive index layer, and an anti-fingerprint layer. However, embodiments of the present disclosure are not limited thereto.

FIG. 3 is a cross-sectional view showing the display panel of FIG. 2.

Referring to FIGS. 1 and 3, the display panel DP may include a substrate SUB, a buffer layer BUF, a gate insulating layer GI, a transistor TR, an interlayer insulating layer IL, a connecting electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not limited thereto, and the substrate SUB may be an inorganic layer, an organic layer, or a composite material layer.

The buffer layer BUF may be disposed on the substrate SUB. The buffer layer BUF may be disposed on the substrate SUB. The buffer layer BUF may prevent impurities such as oxygen and moisture from penetrating into the upper part of the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium GE, and chromium (Cr), titanium (Ti), and zinc (Zn). The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BUF. Specifically, the gate insulating layer GI may cover the active layer ACT on the buffer layer BUF. The gate insulating layer GI may include an inorganic insulating material. In an embodiment, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, or transparent conductive material. Examples of the conductive material that may be used in the gate electrode GE may include gold (Au), silver (Ag), aluminum (Al), platinum (PT), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN) chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. Alternatively, the gate electrode GE may have a single-layer structure or a multi-layer structure including a plurality of conductive layers.

The interlayer insulating layer IL may be disposed on the gate electrode GE. Specifically, the interlayer insulating layer IL may be disposed on the gate insulating layer GI and cover the gate electrode GE on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. Specifically, the first via layer VIA1 may be disposed on the interlayer insulating layer IL and cover the source electrode SE and the drain electrode DE on the interlayer insulating layer IL. The first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include metal, alloy, metal nitride, conductive metal oxide, transparent conductive material, etc. These may be used alone or in combination with each other. However, embodiments of the present disclosure are not limited thereto.

The second via layer VIA2 may be disposed on the connection electrode CNE. Specifically, the second via layer VIA2 may be disposed on the first via layer VIA1 and cover the connection electrode CNE. The second via layer VIA2 may include substantially a same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. Specifically, the light emitting layer EL may be disposed within an opening defined by the pixel defining layer PDL. That is, the light emitting layer EL may be surrounded by the pixel defining layer PDL. The light emitting layer EL may include at least one of organic light emitting material and/or quantum dots. However, embodiments of the present disclosure are not limited thereto.

The common electrode CE may be disposed on the light emitting layer EL. The common electrode CE may also be disposed on the pixel defining layer PDL. That is, the common electrode CE may be continuously disposed on the light emitting layer EL and the pixel defining layer PDL. The common electrode CE may include a conductive material. The light emitting layer EL may emit light based on voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment, the inorganic encapsulation layer and the organic encapsulation layer may be alternately disposed. For example, the organic encapsulation layer may include a cured polymer such as polyacrylate, epoxy resin, or silicone resin. For example, the inorganic thin film may include silicon oxide, silicon nitride, silicon carbide, aluminum oxide, tantalum oxide, hafnium oxide, zirconium oxide, titanium oxide, etc.

FIG. 4 is an enlarged cross-sectional view of part A of FIG. 2.

Referring to FIGS. 1 and 4, the light blocking member BM may include a first light blocking part BM1 and a second light blocking part BM2. In addition, the display device DD may include a dam DAM between the second light blocking part BM2 and the display panel DP.

The first light blocking part BM1 may be disposed below the window layer WL. That is, the first light blocking part BM1 may directly contact the window layer WL. The first light blocking part BM1 may block light coming from a rear of the display device DD, thereby providing visual convenience to the user of the display device DD.

In an embodiment, a first thickness H1 of the first light blocking part BM1 in the third direction D3 may be about 6 μm to about 20 μm. Preferably, the first thickness H1 of the first light blocking part BM1 may be about 6 μm to about 15 μm. However, embodiments of the present disclosure are not limited thereto.

The first light blocking part BM1 may be disposed in the peripheral area SA of the display device DD. However, embodiments of the present disclosure are not limited thereto. The first light blocking part BM1 may be disposed in a portion of the display area DA of the display device DD (e.g., near the camera of the display device DD).

The second light blocking part BM2 may be disposed between the display panel DP and the first light blocking part BM1. The second light blocking part BM2 may be disposed in contact with a lower surface of the first light blocking part BM1. That is, the second light blocking part BM2 may be disposed on a surface of the first light blocking part BM1 in a direction opposite to the third direction D3. The second light blocking part BM2 may provide a space in which the dam DAM is later disposed. The second light blocking part BM2 may include substantially a same material as the first light blocking part BM1.

In an embodiment, the second light blocking part BM2 may partially cover a lower surface of the first light blocking part BM1. Specifically, a planar area of the second light blocking part BM2 may be less than a planar area of the first light blocking part BM1. As the second light blocking part BM2 partially covers the first light blocking part BM1, a lower surface of the first light blocking part BM1 to a lower surface of the second light blocking part BM2 may form a step in the light blocking member BM.

The second thickness H2 of the second light blocking part BM2 may be about 6 μm to about 20 μm. Preferably, the second thickness H2 of the second light blocking part BM2 may be about 6 μm to about 15 μm. However, embodiments of the present disclosure are not limited thereto. By arranging the second thickness H2 of the second light blocking part BM2 satisfying a range described above, a third thickness H3 of the dam DAM may be lowered and the dam DAM may not be spread and be formed to have a vertical shape in the third direction D3.

In an embodiment, as shown in FIG. 4, an end of the second light blocking part BM2 may coincide with an end of the display panel DP in a plan view. Since the second light blocking part BM2 provides a space where the dam DAM is disposed, when an end of the second light blocking part BM2 coincides with an end of the display panel DP, an end of the dam DAM and an end of the display panel DP may coincide.

The dam DAM may be disposed between the light blocking member BM and the display panel DP. The dam DAM may be disposed on a lower surface of the second light blocking part BM2. That is, the dam DAM may be disposed on a lower surface of the second light blocking part BM2 in a direction opposite to the third direction D3. The dam DAM may prevent the adhesive part AD from overflowing.

The dam DAM may include substantially a same material as the adhesive part AD. The dam DAM and the adhesive part AD may include a transparent material. Accordingly, light emitted from the display device DD may be transmitted to the user without being blocked by the dam DAM and the adhesive part AD.

In an embodiment, the dam DAM may be hardened before the adhesive part AD is disposed, thereby preventing the adhesive part AD from overflowing out of the display device DD. To this end, a level of the lower surface of the dam DAM and a level of the lower surface of the adhesive part AD with respect to a lower surface of the window layer WL may be substantially same.

In an embodiment, a sum of the second thickness H2 of the second light blocking part BM2 and the third thickness H3 of the dam DAM may be about 50 μm to about 200 μm. Preferably, a sum of the second thickness H2 of the second light blocking part BM2 and the third thickness H3 of the dam DAM may be about 50 μm to about 150 μm. The adhesive part AD has a thickness of about 50 μm to about 200 μm in the third direction D3. At this time, as a sum of the second thickness H2 of the second light blocking part BM2 and the third thickness H3 of the dam DAM satisfies the above-described range, so that the adhesive part AD may be formed so as not to overflow out of the display panel DP.

In an embodiment, as shown in FIG. 4, an end of the second light blocking part BM2 and the end of the dam DAM may coincide in a plan view. That is, the dam DAM may entirely cover a lower surface of the second light blocking part BM2. Specifically, a planar area of a lower surface of the second light blocking part BM2 may be substantially a same planar area as an upper surface of the dam DAM.

The dam DAM may be disposed in contact with a lower surface of the second light blocking part BM2 and may be spaced apart from a lower surface of the first light blocking part BM1. That is, the dam DAM may be disposed to prevent overflow of the dam DAM from edges of a lower surface of the second light blocking part BM2.

The adhesive part AD may be disposed between the display panel DP and the window layer WL. The adhesive part AD may be disposed in the display area DA of the display device DD. The adhesive part AD may adhere the display panel DP and the window layer WL. The adhesive part AD may have an excellent adhesive effect when it has a thickness of about 50 μm to about 200 μm in the third direction D3. Preferably, the adhesive part AD may have a thickness of about 50 μm to about 150 μm in the third direction D3.

The adhesive part AD may be surrounded by the dam DAM in a plan view. In addition, the adhesive part AD may be surrounded by the light blocking member BM in a plan view. Because the adhesive part AD is surrounded by the dam DAM and the light blocking member BM, the adhesive part AD may not flow out of a region bounded by the dam DAM and the light blocking member BM.

As shown in FIG. 4, as the second light blocking part BM2 is disposed on the first light blocking part BM1 and, thus, the third thickness H3 of the dam DAM may be lower than in an absence of the second light blocking part BM2. As the third thickness H3 of the dam DAM is lower, a spread of the dam DAM is minimized, and thus a lateral slope of the dam DAM may be formed to be close to the vertical along the third direction D3. Accordingly, the dam DAM may be formed so as not to spread beyond the light blocking member BM. As a result, the dam DAM does not contact the window layer WL and, thus, an excellent visual experience may be provided to users of the display device DD.

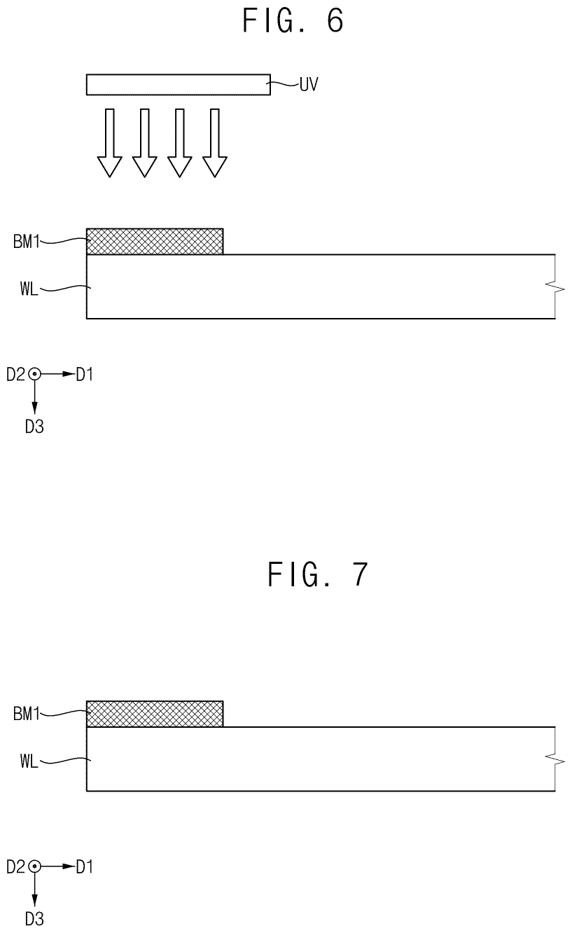

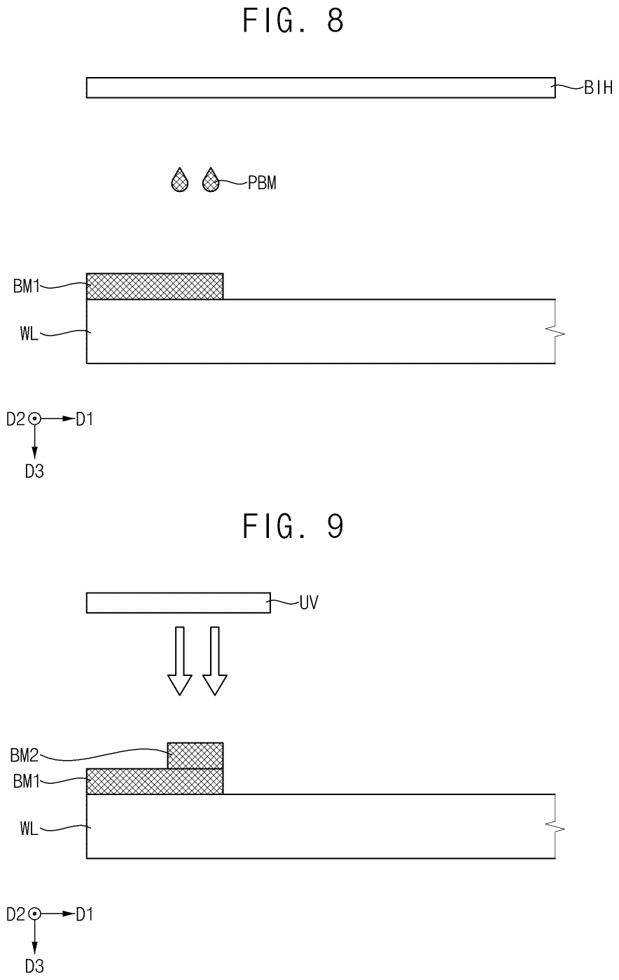

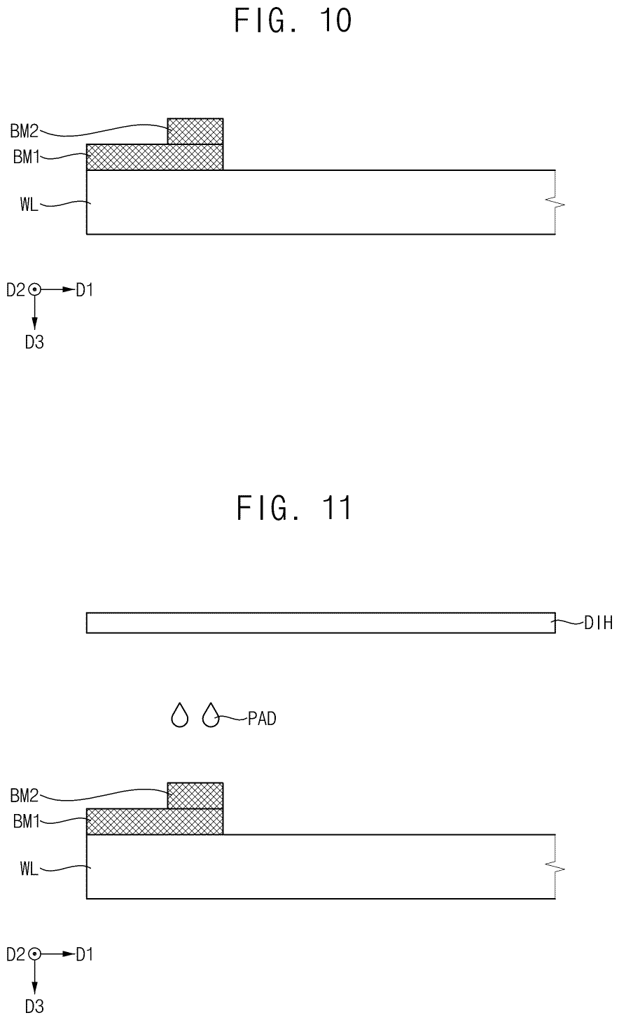

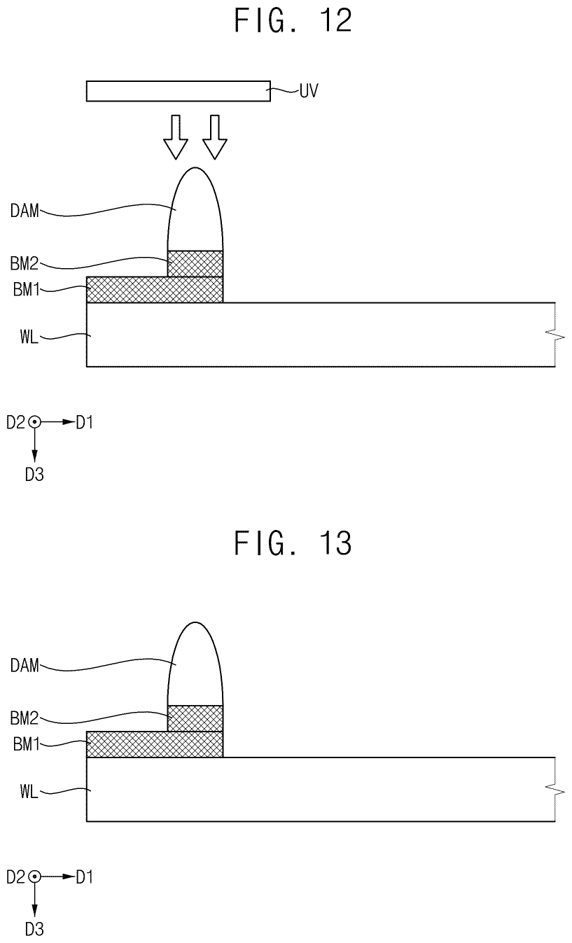

FIGS. 5 to 17 are views showing a manufacturing method for forming the light blocking member and the dam of FIG. 4.

Referring to FIGS. 5, 6, and 7, a light blocking ink head BIH may apply a light blocking material PBM to a surface of the window layer WL. The light blocking material PBM may include pressure sensitive adhesive (PSA), optical clear adhesive (OCA), or optical clear resin (OCR). However, embodiments of the present disclosure are not limited thereto.

The light blocking material PBM may be applied to a surface of the window layer WL and cured by a curing machine UV. The curing machine UV may cure the light blocking material PBM using ultraviolet light. Curing the light blocking material PBM with the curing machine UV may form the first light blocking part BM1.

Referring to FIGS. 8, 9, and 10, the light blocking ink head BIH may apply a light blocking material PBM to a surface of the first light blocking part BM1. Specifically, the light blocking ink head BIH may apply the light blocking material PBM to partially cover a surface of the first light blocking part BM1.

Applying the light blocking material PBM on the first light blocking part BM1 and then curing it with the curing machine UV may form the second light blocking part BM2.

Referring to FIGS. 11, 12, and 13, an adhesive material PAD may be applied on the second light blocking part BM2 by an adhesive ink head DIH. The adhesive material PAD may be applied on the second light blocking part BM2 and not overflow edges of the second light blocking part BM2 due to surface tension. The adhesive material PAD may be applied while covering a surface of the second light blocking part BM2.

Applying the adhesive material PAD may form a semi-elliptical shape in a cross-sectional view. That is, the adhesive material PAD may have a shape that protrudes in a direction opposite to the third direction D3 forming the semi-elliptical shape. The adhesive material PAD may be cured by the curing machine UV.

Applying and curing the adhesive material PAD may form the dam DAM. The dam DAM may completely cover a surface of the second light blocking part BM2 without overflowing edges of a lower surface of the second light blocking part BM2 due to surface tension. Accordingly, an end of the dam DAM and an end of the second light blocking part BM2 may coincide in a plan view. For this reason, the dam DAM may be formed to be in contact with a surface of the second light blocking part BM2 and to be spaced apart from a surface of the first light blocking part BM1.

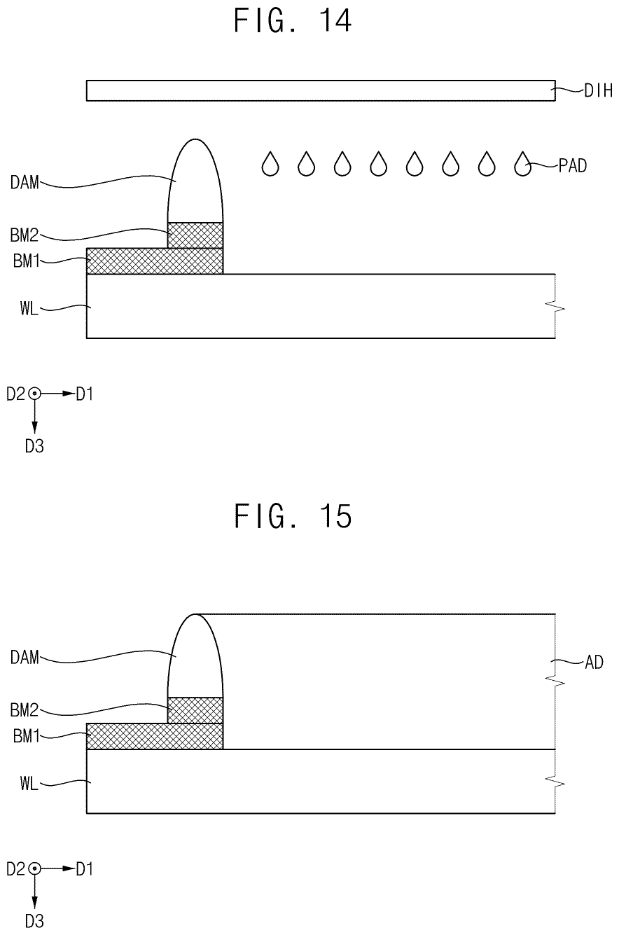

Referring further to FIGS. 14 and 15, the adhesive material PAD may be applied to a surface of the window layer WL by an adhesive ink head DIH. Specifically, the adhesive material PAD may be surrounded by the dam DAM and the light blocking member BM and may be applied in a direction opposite to the third direction D3 on the window layer WL. The adhesive material PAD may be formed into the adhesive part AD that attaches the display panel (e.g., the display panel DP of FIG. 16) to a surface of the window layer WL.

The dam DAM and the adhesive part AD may have a same height. That is, a level of the lower surface of the dam DAM with respect to the lower surface of the window layer WL and a level of the adhesive part AD with respect to the lower surface of the window layer WL may be same. Accordingly, the display panel (e.g., the display panel DP in FIG. 16) may contact the dam DAM and the adhesive part AD.

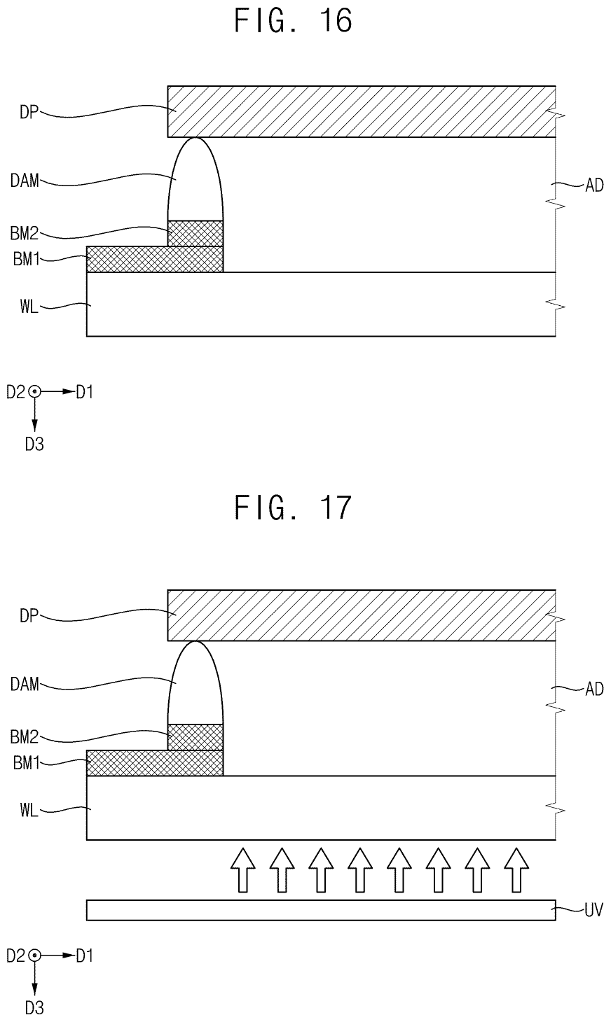

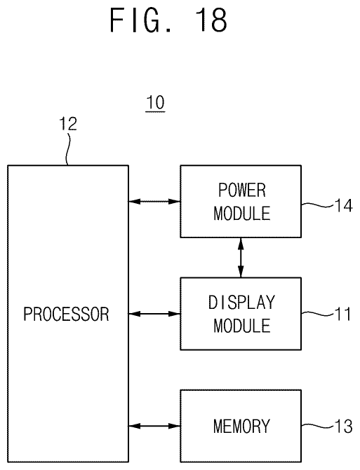

Referring further to FIGS. 16 and 17, the display panel DP may be attached to the adhesive part AD along a direction opposite to the third direction D3. Afterwards, the adhesive part AD is cured by the curing machine UV, and the adhesive part AD and the display panel DP may be adhered. As a result, portion A of FIG. 4 may be formed through the manufacturing process described with reference to FIGS. 5 to 17.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

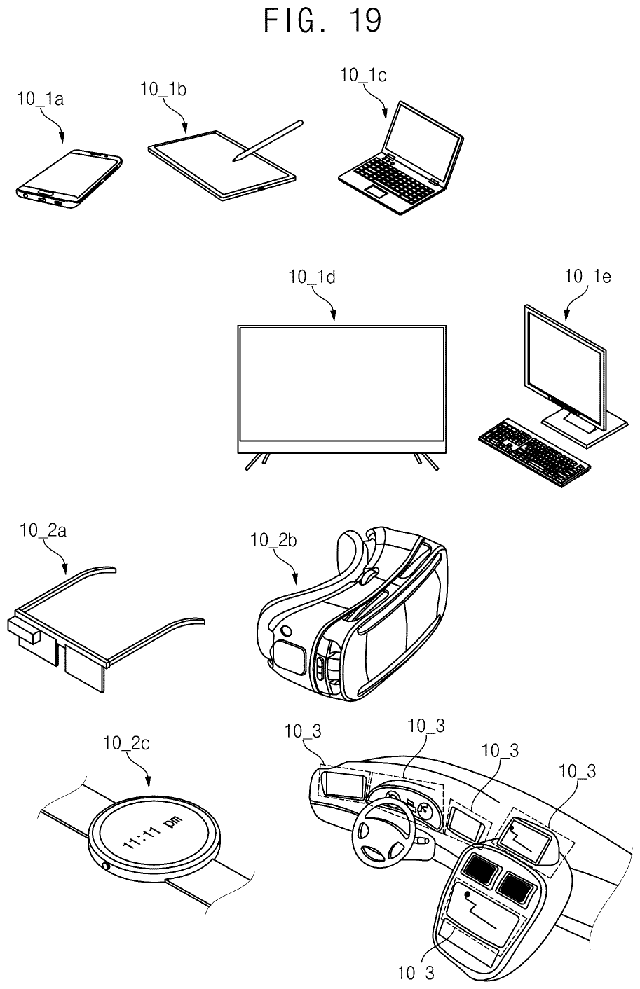

FIG. 18 is block-diagram for showing an electronic device according to an embodiment of the disclosure.

Referring to FIG. 1 and FIG. 18, the display device DD according to the embodiments of present disclosure may be applied to various electronic devices 10. The electronic device 10 according to an embodiment may include the display device DD, and may further include a module or device including additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for an operation of the processor 12 or the display module 11. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to generate power necessary for an operation of the electronic device 10.

At least one of the components of the electronic device 10 described above may be included in the display device according to the embodiments described above. In addition, some of individual modules functionally included in one module may be included in the display device, and other parts may be provided separately from the display device. For example, the display device DD may include the display module 11, and the processor 12, the memory 13, and the power module 14 may be provided in the form of other devices within the electronic device 10 other than the display device DD.

FIG. 19 is schematic views for showing the electronic device according to various embodiments of FIG. 18.

Referring to FIGS. 18 and 19, various electronic devices to which the display device DD according to embodiments is applied may include not only image display electronic devices such as a smart phone 10_1a, a tablet PC 10_1b, a laptop 10_1c, a TV 10_1d, and a desk monitor 10_1e, but also wearable electronic devices including display modules such as smart glasses 10_2a, a head-mounted display 10_2b, and a smart watch 10_2c, and vehicle electronic devices 10_3 including display modules such as a CID (center information display) and a room mirror display placed on a dashboard, center fascia, or dashboard of an automobile.

However, this is exemplary, and the electronic device 10 according to embodiments of the present disclosure is not limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile.

While the disclosure has been particularly shown and described with reference to embodiments thereof, it will be understood by those of ordinary skill in the art that various changes in form and details may be made therein without departing from the spirit or scope of the disclosure as defined by the following claims.

What is claimed is:

1. A display device comprising:
a display panel including a light emitting diode;
a window layer disposed on the display panel;
a light blocking member including:
a first light blocking part disposed between the display panel and the window layer; and
a second light blocking part disposed between the display panel and the first light blocking part and partially covering a lower surface of the first light blocking part; and
a dam disposed between the light blocking member and the display panel.

2. The display device of claim 1, wherein the second light blocking part is disposed contacting a lower surface of the first light blocking part.

3. The display device of claim 2, wherein the light blocking member has a step due to a difference between a width of the first light blocking part and a width of the second light blocking part in a plan view.

4. The display device of claim 1, wherein a thickness of the second light blocking part is about 6 μm to about 20 μm.

5. The display device of claim 1, wherein a sum of the thickness of the second light blocking part and a thickness of the dam is about 50 μm to about 200 μm.

6. The display device of claim 1, wherein an end of the second light blocking part and an end of the display panel coincide with each other in a plan view.

7. The display device of claim 1, wherein an end of the second light blocking part and an end of the dam coincide with each other in a plan view.

8. The display device of claim 1, wherein the dam is disposed contacting a lower surface of the second light blocking part and is spaced apart from a lower surface of the first light blocking part.

9. The display device of claim 1, wherein the dam entirely covers a lower surface of the second light blocking part.

10. The display device of claim 1, wherein the second light blocking part and the dam have a same planar area in a plan view.

11. The display device of claim 1, further comprising:
an adhesive part disposed between the display panel and the window layer.

12. The display device of claim 11, wherein a lower surface of the dam and a lower surface of the adhesive part with respect to a lower surface of the window layer have a same level in a cross-sectional view.

13. The display device of claim 1, wherein the light blocking member surrounds the adhesive part in a plan view.

14. The display device of claim 11, wherein the dam surrounds the adhesive part in a plan view.

15. The display device of claim 11, wherein the dam and the adhesive part include a same material.

16. The display device of claim 11, wherein the dam and the adhesive part are transparent.

17. A method of manufacturing a display device comprising:
forming a first light blocking part on a window layer;
forming a second light blocking part on the first light blocking part partially covering a surface of the first light blocking part; and
forming a dam on the second light blocking part.

18. The method of claim 17, wherein in forming the dam on the second light blocking part, an end of the dam is formed to coincide with an end of the second light blocking part in a plan view.

19. The method of claim 17, wherein in forming the dam on the second light blocking part, the dam is formed to entirely cover a lower surface of the second light blocking part.

20. The method of claim 17, wherein in forming the dam on the second light blocking part, the dam is formed contacting with a lower surface of the second light blocking part and spaced apart from a lower surface of the first light blocking part.

21. An electronic device comprising:
a display device; and
a processor configured to drive the display device, and
wherein the display device includes:
a display panel including a light emitting diode;
a window layer disposed on the display panel;
a light blocking member including:
a first light blocking part disposed between the display panel and the window layer; and
a second light blocking part disposed between the display panel and the first light blocking part and partially covering a lower surface of the first light blocking part; and
a dam disposed between the light blocking member and the display panel.
